(19) United States
(12) Patent Application Publication
(10) Pub. No.: US 2026/0239578 A1
(43) Pub. Date: Aug. 13, 2026

(54) CABINET AND SERVER

(71) Applicant: Fulian Precision Electronics (Tianjin) Co., LTD., Tianjin (CN)

(72) Inventors: Chang-Hsien Chen, New Taipei (TW); Yu-Chen Huang, New Taipei (TW)

(21) Appl. No.: 19/268,772

(22) Filed: Jul. 14, 2025

(30) Foreign Application Priority Data
Feb. 7, 2025 (CN) 202510137867.X

(51) Int. Cl. H05K 7/20

(52) U.S. Cl. CPC H05K 7/20772

(57) ABSTRACT

A cabinet of a server includes a support, a cooling plate, and a bracket. The support is used for positioning a motherboard, which includes a central processing unit and a motherboard-hole. The cooling plate is in thermal contact with the central processing unit for cooling and includes a cooling plate-hole. The bracket connects the cooling plate to the motherboard, with the cooling plate fixed to the motherboard via the bracket. The bracket is bent to form a lower section, a middle section, and an upper section connected sequentially. The lower section includes a motherboard-fixing structure, and the upper section includes a cooling plate-fixing structure. The motherboard-fixing structure fits the motherboard-hole with an adjustable relative position, and the cooling plate-fixing structure fits the cooling plate-hole with an adjustable relative position, enabling the cooling plate’s position relative to the central processing unit to be adjustable.

### FIELD

The disclosure herein generally relates to information computing systems, and more particularly relates to a cabinet and a server.

### BACKGROUND

Servers usually cool the central processing unit on the motherboard by a cooling plate, but the position of the cooling plate relative to the motherboard cannot be adjusted, sometimes the cooling plate deviates from the processor after installation, resulting in insufficient contact between the cooling plate and the central processing unit, reducing cooling efficiency.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a server in an embodiment of the present application.

FIG. 2 is an exploded view of a cooling plate and brackets in the server shown in FIG. 1.

FIG. 3 is an isometric view of one of the brackets in FIG. 1.

FIG. 4 is an isometric view of a bracket in another embodiment of the present application.

FIG. 5 is a cross-sectional view of another embodiment of a bracket and a cooling plate in a server, according to the present application.

FIG. 6 is a top view of a cooling plate and brackets in FIG. 1.

### DETAILED DESCRIPTION

It will be appreciated that for simplicity and clarity of illustration, where appropriate, reference numerals have been repeated among the different FIG. to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

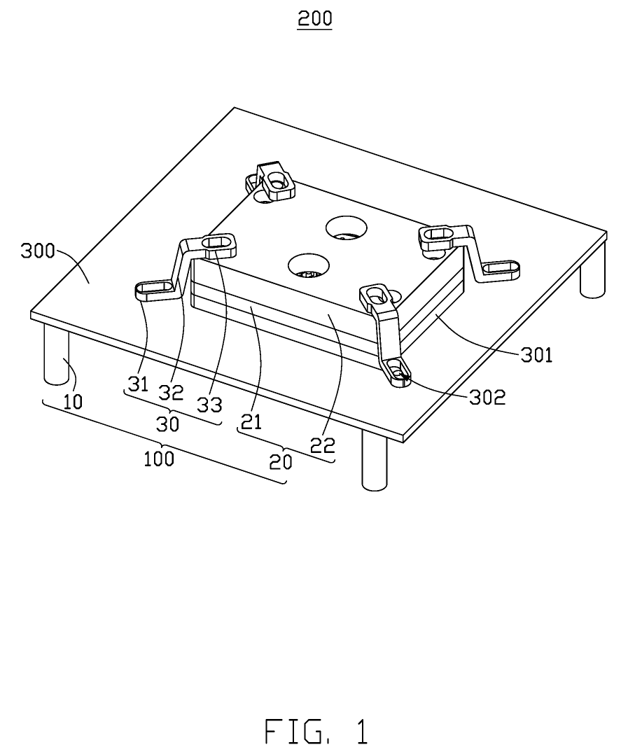

As shown in FIG. 1 to FIG. 3, an embodiment of the present application provides a server 200, which includes a cabinet 100 and a motherboard 300. The motherboard 300 is provided with a central processing unit 301. The cabinet 100 includes a support 10, a cooling plate 20, and a bracket 30. The support 10 is used for positioning the motherboard 300. The motherboard 300 is provided with a motherboard-hole 302 near the central processing unit 301. The cooling plate 20 is used for cooling the central processing unit 301. The cooling plate 20 is provided with a cooling plate-hole 20a. The bracket 30 is used for positioning the cooling plate 20 to the central processing unit 301. The bracket 30 includes a lower section 31, a middle section 32, and an upper section 33, which are sequentially connected. The lower section 31 includes a motherboard-fixing structure 311. The motherboard-fixing structure 311 fits the motherboard-hole 302 to fix the bracket 30 to the motherboard 300. The upper section 33 includes a cooling plate-fixing structure 331. The cooling plate-fixing structure 331 fits the cooling plate-hole 20a to fix the bracket 30 to the cooling plate 20. A position of the motherboard-fixing structure 311 relative to the motherboard-hole 302 is adjustable, and a position of the cooling plate-fixing structure 331 relative to the cooling plate-hole 20a is adjustable, so that a position of the cooling plate 20 relative to the central processing unit 301 is adjustable. The cooling plate 20 is fixed to the motherboard 300 through the bracket 30, so that the position of the cooling plate 20 relative to the central processing unit 301 is fixed. The cooling plate 20 is not directly fixed to the central processing unit 301, and there is no direct fixed connection between the cooling plate 20 and the central processing unit 301. The cooling plate 20 only contacts the central processing unit 301 to achieve cooling.

In some embodiments, referring to FIG. 1 to FIG. 3, a specific method A for adjusting the position of the bracket 30 relative to the motherboard 300 is as follows: The cabinet 100 further includes a screw. The motherboard-hole 302 is a screw hole. The motherboard-fixing structure 311 is a strip hole. The screw hole is selectively aligned with any position of the strip hole, so that the position of the bracket 30 relative to the motherboard 300 is adjustable. A screw passes through the strip hole and threads into the screw hole. A screwhead of the screw presses the lower section 31 to fix the bracket 30 to the motherboard 300.

In some embodiments, referring to FIG. 1 to FIG. 3, a specific method B for adjusting the position of the bracket 30 relative to the cooling plate 20 is as follows: The cabinet 100 further includes a screw. The cooling plate-hole 20a is a screw hole. The cooling plate-fixing structure 331 is a strip hole. The screw hole is selectively aligned with any position of the strip hole, so that the position of the bracket 30 relative to the cooling plate 20 is adjustable. A screw passes through the strip hole and threads into the screw hole. A screwhead of the screw presses the upper section 33 to fix the bracket 30 to the cooling plate 20.

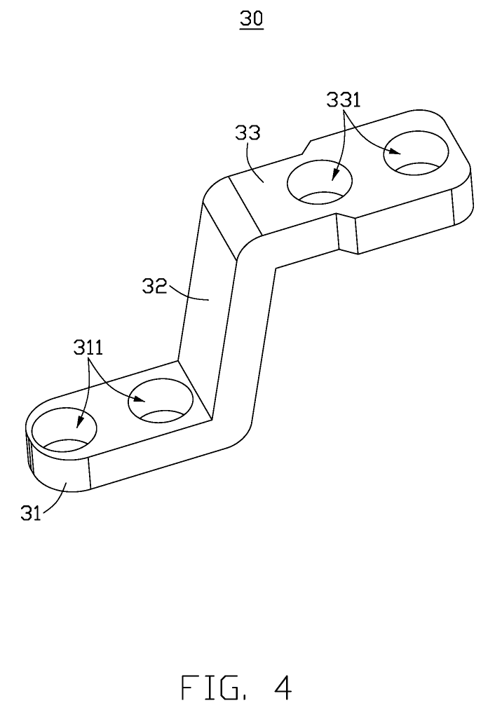

In some embodiments, referring to FIG. 4, a specific method C for adjusting the position of the bracket 30 relative to the motherboard 300 is as follows: The cabinet 100 further includes a screw. The motherboard-hole 302 is a screw hole. The motherboard-fixing structure 311 includes a plurality of round holes. The screw hole is selectively aligned with one of the plurality of round holes, so that the position of the bracket 30 relative to the motherboard 300 is adjustable. A screw passes through the one of the plurality of round holes aligned with the screw hole and threads into the screw hole. A screwhead of the screw presses the lower section 31 to fix the bracket 30 to the motherboard 300.

In some embodiments, referring to FIG. 4, a specific method D for adjusting the position of the bracket 30 relative to the cooling plate 20 is as follows: The cabinet 100 further includes a screw. The cooling plate-hole 20a is a screw hole. The cooling plate-fixing structure 331 includes a plurality of round holes. The screw hole is selectively aligned with one of the plurality of round holes, so that the position of the bracket 30 relative to the cooling plate 20 is adjustable. A screw passes through the one of the plurality of round holes aligned with the screw hole and threads into the screw hole. A screwhead of the screw presses the upper section 33 to fix the bracket 30 to the cooling plate 20.

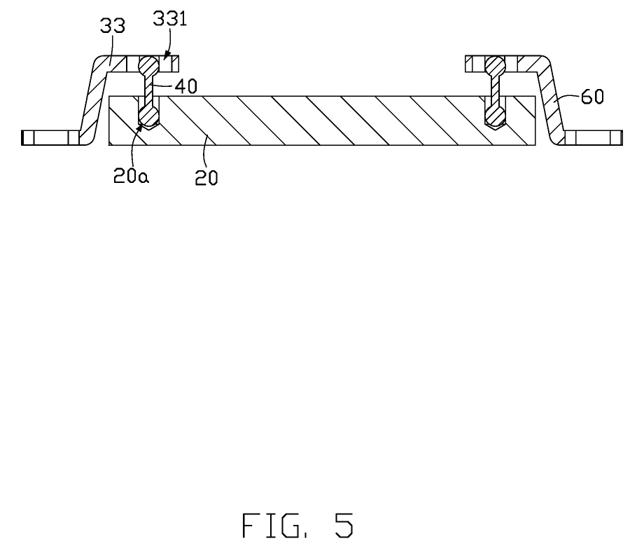

In some embodiments, referring to FIG. 5, a specific method E for adjusting the position of the bracket 30 relative to the cooling plate 20 is as follows: The cooling plate-hole 20a and the cooling plate-fixing structure 331 are ball holes. The cabinet 100 further includes a rod 40 with two ball joints on both ends. One of the two ball joints is rotatably inserted in the cooling plate-hole 20a. Another one of the two ball joints is rotatably inserted in the cooling plate-fixing structure 331, so that the position of the bracket 30 relative to the cooling plate 20 is adjustable.

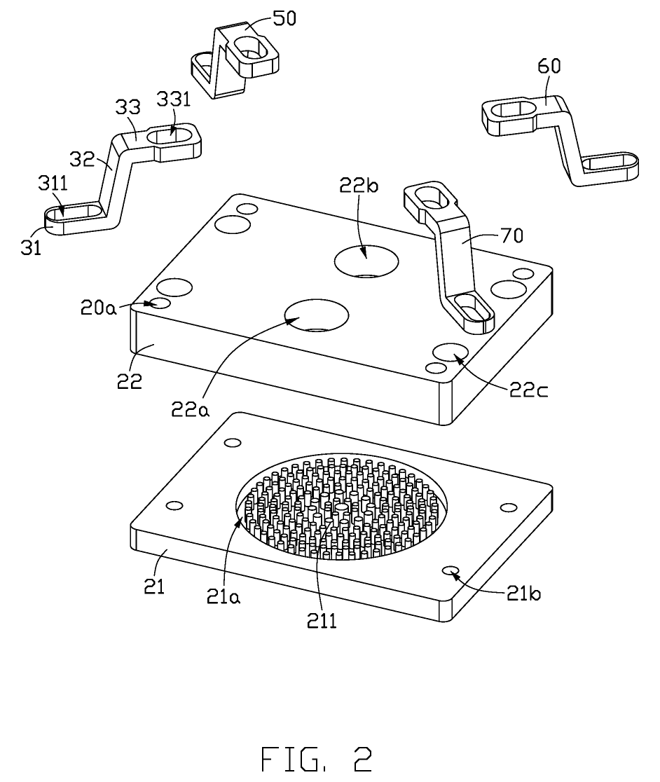

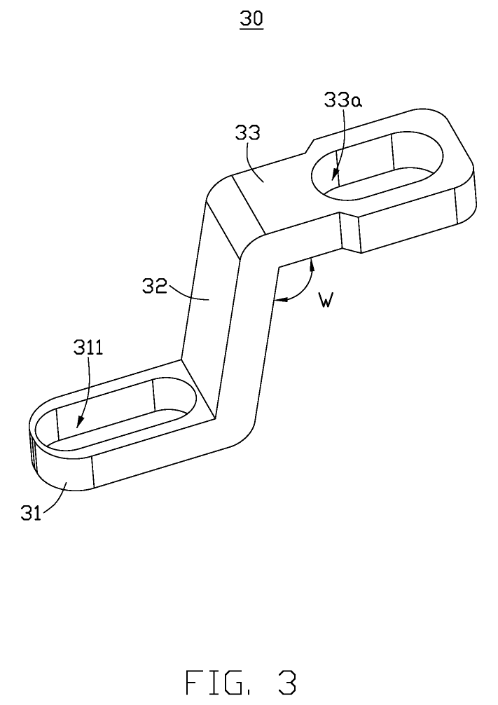

In some embodiments, referring to FIG. 2 and FIG. 3, projections of the lower section 31, the middle section 32, and the upper section 33 on the motherboard 300 extend straightly along a same direction. The lower section 31 and the upper section 33 are parallel to the motherboard 300 to facilitate the manufacturing of the bracket 30. A height difference is defined between the lower section 31 and the upper section 33 relative to the motherboard 300. The middle section 32 is inclined relative to the lower section 31 and the upper section 33, and an angle between the middle section 32 and the lower section 31 is an obtuse angle. Compared to a right angle, this reduces the risk of stress concentration and enhances the stability of the bracket 30.

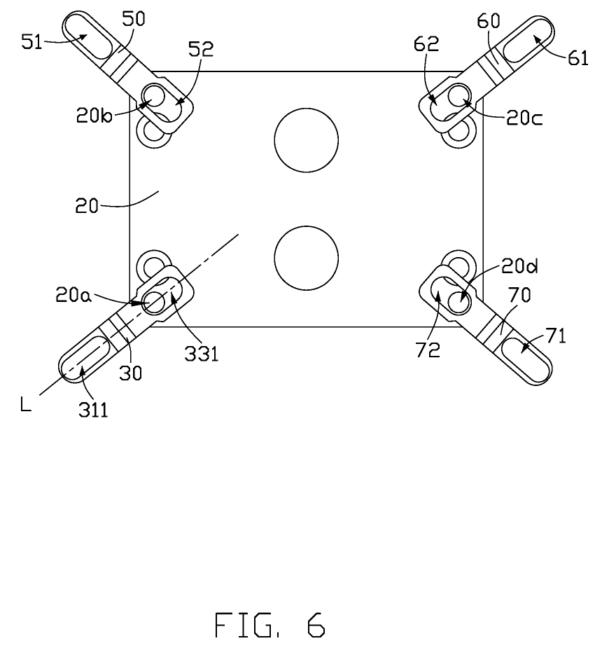

In some embodiments, referring to FIG. 2 and FIG. 6, the central processing unit 301 is in the shape of a rectangular sheet. Correspondingly, the cooling plate 20 is also in the shape of a rectangular parallelepiped. To enhance the stability of the cooling plate 20 relative to the central processing unit 301, additional brackets are added based on the bracket 30. For example, the cabinet 100 further includes a bracket 50, a bracket 60, and a bracket 70. The bracket 30, bracket 50, bracket 60, and bracket 70 are respectively provided at the four corners of the cooling plate 20 to enhance stability.

The bracket 50 includes a motherboard-fixing structure 51 and a cooling plate-fixing structure 52. The bracket 60 includes a motherboard-fixing structure 61 and a cooling plate-fixing structure 62. The bracket 70 includes a motherboard-fixing structure 71 and a cooling plate-fixing structure 72.

Correspondingly, the motherboard 300 is further provided with three additional motherboard-holes 302. The cooling plate 20 is further provided with a cooling plate-hole 20b, a cooling plate-hole 20c, and a cooling plate-hole 20d. The bracket 50 connects to a motherboard-hole 302 and the cooling plate-hole 20b through the motherboard-fixing structure 51 and the cooling plate-fixing structure 52, respectively. The bracket 60 connects to a motherboard-hole 302 and the cooling plate-hole 20c through the motherboard-fixing structure 61 and the cooling plate-fixing structure 62, respectively. The bracket 70 connects to a motherboard-hole 302 and the cooling plate-hole 20d through the motherboard-fixing structure 71 and the cooling plate-fixing structure 72, respectively.

The bracket 50, bracket 60, and bracket 70 may have the same structure as the bracket 30. The three additional motherboard-holes may have the same structure as the motherboard-hole 302. The cooling plate-hole 20b, cooling plate-hole 20c, and cooling plate-hole 20d may have the same structure as the cooling plate-hole 20a.

Alternatively, bracket 30, bracket 50, bracket 60, and bracket 70 may differ and can be selected from methods A to E based on different usage scenarios. For example, the diagonally opposite bracket 30 and bracket 60 are the same, and the fixing methods of the bracket 30 and bracket 60 with the motherboard 300 and the cooling plate 20 adopt method A and method B, respectively. The diagonally opposite bracket 50 and bracket 70 are the same, and the fixing methods of the bracket 50 and bracket 70 with the motherboard 300 and the cooling plate 20 adopt method A and method E, respectively. Since method E does not require the installation of a screw, it enhances operational convenience while ensuring stability.

In some embodiments, referring to FIG. 1 and FIG. 2, the cooling plate 20 includes a lower board 21 and an upper board 22. The lower board 21 and the upper board 22 are covered with each other to form a complete cooling plate 20. A cavity 21a is provided on a side of the lower board 21 facing the upper board 22. The upper board 22 includes an inlet hole 22a and an outlet hole 22b. The inlet hole 22a and the outlet hole 22b are connected with the cavity 21a. A side of the lower board 21 facing away from the upper board 22 is attached to the central processing unit 301. Coolant enters the cavity 21a through the inlet hole 22a and then flows out from the outlet hole 22b, absorbing heat from the central processing unit 301.

Optionally, the lower board 21 includes a plurality of columns 211 in the cavity 21a. The plurality of columns 211 are used for reducing a velocity of flow of the coolant, allowing the coolant to stay in the cavity 21a for a longer time to absorb more heat from the central processing unit 301, thereby improving heat transfer efficiency.

Optionally, a cross-section of the cavity 21a is circular. One of the plurality of columns 211 is set at a center of the cavity 21a. A plurality of circles with different diameters are defined around the center of the cavity 21a. The plurality of columns 211 are arranged along each of the plurality of circles. The inlet hole 22a and the outlet hole 22b are set symmetrically about an axis of the cavity 21a, allowing the columns 211 to be more evenly distributed to reduce the velocity of flow of the coolant more efficiently.

In some embodiments, the lower board 21 includes a lower mounting hole 21b, and the upper board 22 includes an upper mounting hole 22c. The lower mounting hole 21b aligns with the upper mounting hole 22c and is used to install a screw to fix the lower board 21 and the upper board 22, thereby forming a complete cooling plate 20.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A cabinet of a server comprising:
a support configured for positioning a motherboard with a central processing unit;
a cooling plate configured for cooling the central processing unit; and
a bracket configured for positioning the cooling plate to the central processing unit, wherein the bracket comprises a lower section, a middle section, and an upper section, the lower section comprises a motherboard-fixing structure, the motherboard-fixing structure fits a motherboard-hole on the motherboard to fix the bracket to the motherboard, the upper section comprises a cooling plate-fixing structure, the cooling plate-fixing structure fits a cooling plate-hole on the cooling plate to fix the bracket to the cooling plate, a position of the motherboard-fixing structure relative to the motherboard-hole is adjustable, and a position of the cooling plate-fixing structure relative to the cooling plate-hole is adjustable, such that a position of the cooling plate relative to the central processing unit is adjustable.

2. The cabinet of claim 1, wherein the motherboard-hole is a screw hole, the motherboard-fixing structure is a strip hole, the screw hole is selectively aligned with any position of the strip hole, so that the position of the bracket relative to the motherboard is adjustable, a screw passes through the strip hole and threads into the screw hole, and a screwhead of the screw press the lower section to fix the bracket to the motherboard.

3. The cabinet of claim 1, wherein the cooling plate-hole is a screw hole, the cooling plate-fixing structure is a strip hole, the screw hole is selectively aligned with any position of the strip hole, so that the position of the bracket relative to the cooling plate is adjustable, a screw passes through the strip hole and threads into the screw hole, and a screwhead of the screw press the upper section to fix the bracket to the cooling plate.

4. The cabinet of claim 1, wherein the motherboard-hole is a screw hole, the motherboard-fixing structure comprises a plurality of round holes, the screw hole is selectively aligned with one of the plurality of round holes, so that the position of the bracket relative to the motherboard is adjustable, a screw passes through the one of the plurality of round holes aligned with the screw hole, and threads into the screw hole, and a screwhead of the screw press the lower section to fix the bracket to the motherboard.

5. The cabinet of claim 1, wherein the cooling plate-hole is a screw hole, the cooling plate-fixing structure comprises a plurality of round holes, the screw hole is selectively aligned with one of the plurality of round holes, so that the position of the bracket relative to the cooling plate is adjustable, a screw passes through the one of the plurality of round holes aligned with the screw hole, and threads into the screw hole, and a screwhead of the screw press the upper section to fix the bracket to the cooling plate.

6. The cabinet of claim 1, wherein the cooling plate-hole and the cooling plate-fixing structure are ball holes, the cabinet further comprises a rod with two ball joints on both ends, one of the two ball joints is rotatably inserted in the cooling plate-hole, another one of the two ball joints is rotatably inserted in the cooling plate-fixing structure, so that the position of the bracket relative to the cooling plate is adjustable.

7. The cabinet of claim 1, wherein projections of the lower section, the middle section, and the upper section on the motherboard extend straightly along a same direction, the lower section and the upper section are parallel to the motherboard, a height difference is defined between the lower section and the upper section relative to the motherboard, the middle section is inclined relative to the lower section and the upper section, and an angle between the middle section and the lower section is an obtuse angle.

8. The cabinet of claim 7, wherein the cooling plate comprises a lower board and an upper board, the lower board and the upper board are covered with each other, a cavity is provided on a side of the lower board facing the upper board, the upper board comprises a inlet hole and an outlet hole, the inlet hole and the outlet hole are connected with the cavity, a side of the lower board facing away from the upper board is attached to the central processing unit, coolant enters the cavity through the inlet hole and then flows out from the outlet hole.

9. The cabinet of claim 8, wherein the lower board comprises a plurality of columns in the cavity, the plurality of columns is configured for reducing a velocity of flow of the coolant.

10. The cabinet of claim 9, wherein one of the plurality of columns is set at a center of the cavity, a plurality of circles with different diameters are defined around the center of the cavity, the plurality of columns is arranged along each of the plurality of circles, the inlet hole and the outlet hole are set symmetrically about an axis of the cavity.

11. A server comprising:
a motherboard with a central processing unit; and
a cabinet comprising:
a support configured for positioning the motherboard;
a cooling plate configured for cooling the central processing unit; and
a bracket configured for positioning the cooling plate to the central processing unit, wherein the bracket comprises a lower section, a middle section, and an upper section, the lower section comprises a motherboard-fixing structure, the motherboard-fixing structure fits a motherboard-hole on the motherboard to fix the bracket to the motherboard, the upper section comprises a cooling plate-fixing structure, the cooling plate-fixing structure fits a cooling plate-hole on the cooling plate to fix the bracket to the cooling plate, a position of the motherboard-fixing structure relative to the motherboard-hole is adjustable, and a position of the cooling plate-fixing structure relative to the cooling plate-hole is adjustable, such that a position of the cooling plate relative to the central processing unit is adjustable.

12. The server of claim 11, wherein the motherboard-hole is a screw hole, the motherboard-fixing structure is a strip hole, the screw hole is selectively aligned with any position of the strip hole, so that the position of the bracket relative to the motherboard is adjustable, a screw passes through the strip hole and threads into the screw hole, and a screwhead of the screw press the lower section to fix the bracket to the motherboard.

13. The server of claim 11, wherein the cooling plate-hole is a screw hole, the cooling plate-fixing structure is a strip hole, the screw hole is selectively aligned with any position of the strip hole, so that the position of the bracket relative to the cooling plate is adjustable, a screw passes through the strip hole and threads into the screw hole, and a screwhead of the screw press the upper section to fix the bracket to the cooling plate.

14. The server of claim 11, wherein the motherboard-hole is a screw hole, the motherboard-fixing structure comprises a plurality of round holes, the screw hole is selectively aligned with one of the plurality of round holes, so that the position of the bracket relative to the motherboard is adjustable, a screw passes through the one of the plurality of round holes aligned with the screw hole, and threads into the screw hole, and a screwhead of the screw press the lower section to fix the bracket to the motherboard.

15. The server of claim 11, wherein the cooling plate-hole is a screw hole, the cooling plate-fixing structure comprises a plurality of round holes, the screw hole is selectively aligned with one of the plurality of round holes, so that the position of the bracket relative to the cooling plate is adjustable, a screw passes through the one of the plurality of round holes aligned with the screw hole, and threads into the screw hole, and a screwhead of the screw press the upper section to fix the bracket to the cooling plate.

16. The server of claim 11, wherein the cooling plate-hole and the cooling plate-fixing structure are ball holes, the cabinet further comprises a rod with two ball joints on both ends, one of the two ball joints is rotatably inserted in the cooling plate-hole, another one of the two ball joints is rotatably inserted in the cooling plate-fixing structure, so that the position of the bracket relative to the cooling plate is adjustable.

17. The server of claim 11, wherein projections of the lower section, the middle section, and the upper section on the motherboard extend straightly along a same direction, the lower section and the upper section are parallel to the motherboard, a height difference is defined between the lower section and the upper section relative to the motherboard, the middle section is inclined relative to the lower section and the upper section, and an angle between the middle section and the lower section is an obtuse angle.

18. The server of claim 17, wherein the cooling plate comprises a lower board and an upper board, the lower board and the upper board are covered with each other, a cavity is provided on a side of the lower board facing the upper board, the upper board comprises a inlet hole and an outlet hole, the inlet hole and the outlet hole are connected with the cavity, a side of the lower board facing away from the upper board is attached to the central processing unit, coolant enters the cavity through the inlet hole and then flows out from the outlet hole.

19. The server of claim 18, wherein the lower board comprises a plurality of columns in the cavity, the plurality of columns is configured for reducing a velocity of flow of the coolant.

20. The server of claim 19, wherein one of the plurality of columns is set at a center of the cavity, a plurality of circles with different diameters are defined around the center of the cavity, the plurality of columns is arranged along each of the plurality of circles, the inlet hole and the outlet hole are set symmetrically about an axis of the cavity.
